(19) United States
(12) Patent Application Publication
(10) Pub. No.: US 2012/0052658 A1
(43) Pub. Date: Mar. 1, 2012

(54) QUANTUM DOT FORMING METHOD, STORAGE MEDIUM STORING A PROGRAM AND SUBSTRATE PROCESSING APPARATUS FOR EXECUTION OF THE METHOD

(75) Inventors: Song Yun KANG, Nirasaki City (JP); Satohiko HOSHINO, Nirasaki City (JP)

(73) Assignee: TOKYO ELECTRON LIMITED, Tokyo (JP)

(21) Appl. No.: 13/216,848

(22) Filed: Aug. 24, 2011

(30) Foreign Application Priority Data
Aug. 24, 2010 (JP) 2010-187318

(51) Int. Cl. H01L 21/20; B05C 9/08; B82Y 30/00; B82Y 40/00

(52) U.S. Cl. 438/478; 118/723 R; 257/E21.09; 977/774; 977/890; 977/948

(57) ABSTRACT

A quantum dot forming method for forming quantum dots on a surface of a substrate includes exciting a substrate surface with a laser beam having a standing wave which is irradiated from one side of the substrate along the surface of the substrate to excite the surface of the substrate at an interval of one half of a wavelength of the standing wave, and forming a quantum dot with a film differing in lattice constant from a base film forming the surface of the substrate by allowing the film differing in lattice constant to grow on the substrate to form the quantum dots in excited spots of the surface of the substrate.

### CROSS-REFERENCE TO RELATED APPLICATION

This application is based upon and claims the benefit of priority from Japanese Patent Application No. 2010-187318, filed on Aug. 24, 2010, the entire contents of which are incorporated herein by reference.

### TECHNICAL FIELD

The present disclosure relates to a method of forming quantum dots on a substrate such as a semiconductor wafer, a liquid crystal substrate or a solar cell substrate, a storage medium storing a program and a substrate processing apparatus for execution of the method.

### BACKGROUND

In recent years, attention is paid to application of quantum dots to a photoelectric device. The quantum dots are capable of concentrating electrons in a specific energy state and, therefore, are very useful either as light-emitting materials or as solar cell materials. As a method of forming quantum dots, there is conventionally available a method using an SK (Stranski Krastanov) mode. In the SK mode, quantum dots are formed using the strain energy attributable to the difference in lattice constants of a base crystalline material and a deposited crystalline material and also using the self-organizing phenomenon appearing during crystal growth.

More specifically, if a crystalline material differing in lattice constant from a base crystalline material forming a substrate surface is deposited on the substrate surface, the deposited crystalline material tends to grow such that the lattice constant thereof coincide with the lattice constant of the base crystalline material. In reality, however, the lattice constant of the deposited crystalline material differs from that of the base crystalline material. Thus, the deposited crystalline material undergoes a compressive strain along with the growth thereof. As the growth processes, the crystalline material deposited on a substrate acts to reduce the strain energy. An SK mode occurs just when the thickness of the crystalline material becomes greater than a critical film thickness. As a consequence, the growing film is changed to an island-shaped structure and this portion grows as quantum dots.

Since the self-organizing phenomenon appearing during the crystal growth is used in forming the quantum dots by the SK mode, there is a problem in that it is extremely difficult to control the positions of forming the quantum dots.

Many methods have been developed to control the position of quantum dots. For instance, there is a technique of defining in advance depressions or fine holes in specified positions of a substrate surface where quantum dots are to be formed and then forming quantum dots in the depressions or fine holes. There is also a technique of applying a surface wave (elastic wave) on a substrate and forming quantum dots in the spots corresponding to the wavelength of the elastic wave.

However, the technique of forming quantum dots after defining depressions or fine holes on a substrate surface has a drawback in that other structures such as depressions or fine holes need to be added to the substrate surface. In the technique of applying a surface wave (elastic wave) on a substrate, the propagation of the elastic wave varies according to the structure of the substrate surface. Therefore, there is a possibility that the quantum dots actually formed deviate from desired positions.

### SUMMARY

The present disclosure provides some embodiments of a quantum dot forming method capable of, through irradiation of a laser beam, accurately forming quantum dots in desired positions regardless of the structure of a substrate surface.

According to a first aspect of the present disclosure, there is provided a quantum dot forming method for forming quantum dots on a surface of a substrate, the method including: exciting a substrate surface with a laser beam having a standing wave which is irradiated from one side of the substrate along the surface of the substrate to excite the surface of the substrate at an interval of one half of a wavelength of the standing wave; and forming a quantum dot with a film differing in lattice constant from a base film forming the surface of the substrate by allowing the film differing in lattice constant to grow on the substrate to form the quantum dots in excited spots of the surface of the substrate.

According to a second aspect of the present disclosure, there is provided a computer-readable storage medium storing a program for executing a method of forming quantum dots on a surface of a substrate in a computer, the method including: exciting a substrate surface with a laser beam having a standing wave which is irradiated from one side of the substrate along the surface of the substrate to excite the surface of the substrate at an interval of one half of a wavelength of the standing wave; and forming a quantum dot with a film differing in lattice constant from a base film forming the surface of the substrate by allowing the film differing in lattice constant to grow on the substrate to form the quantum dots in excited spots of the surface of the substrate.

With the present disclosure, it is possible to excite desired spots of the substrate surface at a desired interval by irradiating the laser beam having a standing wave from one side of the substrate along the substrate surface and to form the quantum dots in the excited spots. This eliminates the possibility of generating an elastic wave on the substrate surface and makes it possible to form the quantum dots in desired positions regardless of the structure of the substrate surface.

According to a third aspect of the present disclosure, there is provided a substrate processing apparatus for performing a process of forming quantum dots on a surface of a substrate, the apparatus including: a substrate surface excitation process unit configured to perform, prior to forming the quantum dot, a process for exciting desired spots of the surface of the substrate on which the quantum dots are to be formed; and a quantum dot formation process unit configured to perform a process for forming the quantum dots in excited spots of the surface of the substrate by growing a film differing in lattice constant from a base film forming the surface of the substrate to grow on the substrate, the substrate surface excitation process unit including a stage configured to support the substrate, a laser beam source configured to irradiate a laser beam having a standing wave from one side of the substrate placed on the stage along the surface of the substrate, and a drive mechanism configured to drive the laser beam source at least in a direction perpendicular to a laser beam irradiation direction.

### BRIEF DESCRIPTION OF THE DRAWINGS

The accompanying drawings, which are incorporated in and constitute a part of the specification, illustrate embodiments of the disclosure, and together with the general description given above and the detailed description of the embodiments given below, serve to explain the principles of the disclosure.

FIG. 1 is a conceptual diagram for explaining the principle of a substrate surface excitation process according to one embodiment where desired spots on a substrate surface are excited by a laser beam.

FIG. 2 is a conceptual diagram for explaining a process where quantum dots Q are formed by performing a film formation process on a substrate through an SK mode.

FIG. 3 is a perspective view schematically showing the configuration of a substrate surface excitation unit (substrate surface excitation process unit) according to the present embodiment.

FIG. 4 is a cross-sectional view of the substrate surface excitation unit shown in FIG. 3.

FIG. 5 is a flowchart illustrating one specific example of the substrate surface excitation process performed by a control unit in the present embodiment.

FIG. 6A is an operation explanation view for explaining the substrate surface excitation process where a laser beam source is located in a standby position to.

FIG. 6B is an operation explanation view for explaining the substrate surface excitation process where the laser beam source is located in an excitation start position t1.

FIG. 6C is an operation explanation view for explaining the substrate surface excitation process where the laser beam source is located in a next position t2.

FIG. 6D is an operation explanation view for explaining the substrate surface excitation process where the laser beam source is located in an excitation end position tn.

FIG. 7 is an operation explanation view for explaining a case of changing a specified interval at which a laser beam source is turned on.

FIG. 8 is an operation explanation view for explaining a case of changing of a laser beam wavelength.

FIG. 9 is a conceptual diagram for explaining the principle of another substrate surface excitation process according to the present embodiment.

FIG. 10A is an operation explanation view for explaining another substrate surface excitation process illustrated in FIG. 9 where a line including a specific area A is excited.

FIG. 10B is an operation explanation view for explaining another substrate surface excitation process illustrated in FIG. 9 where a line including a specific area B is excited.

FIG. 10C is an operation explanation view for explaining another substrate surface excitation process illustrated in FIG. 9 where a line including a specific area C is excited.

FIG. 11 is a perspective view showing a modified example of the substrate surface excitation unit according to the present embodiment.

FIG. 12 is an operation explanation view for explaining a substrate surface excitation process performed by the substrate surface excitation unit shown in FIG. 11 where two laser beams having the same wavelength are irradiated.

FIG. 13 is an operation explanation view for explaining a substrate surface excitation process performed by the substrate surface excitation unit shown in FIG. 11 where two laser beams having different wavelengths are irradiated.

FIG. 14 is an operation explanation view for explaining a substrate surface excitation process performed by the substrate surface excitation unit shown in FIG. 11 where the Y-directional positions of two laser beam sources are changed.

FIG. 15 is a cross-sectional view schematically showing a substrate processing apparatus to which the substrate surface excitation unit of the present embodiment is applicable.

### DETAILED DESCRIPTION

Certain preferred embodiments of the present disclosure will now be described in detail with reference to the accompanying drawings. In the subject specification and drawings, those components having substantially the same functions will be designated by the same reference numerals and will not be described repeatedly.

### (Principle of Substrate Surface Excitation Process)

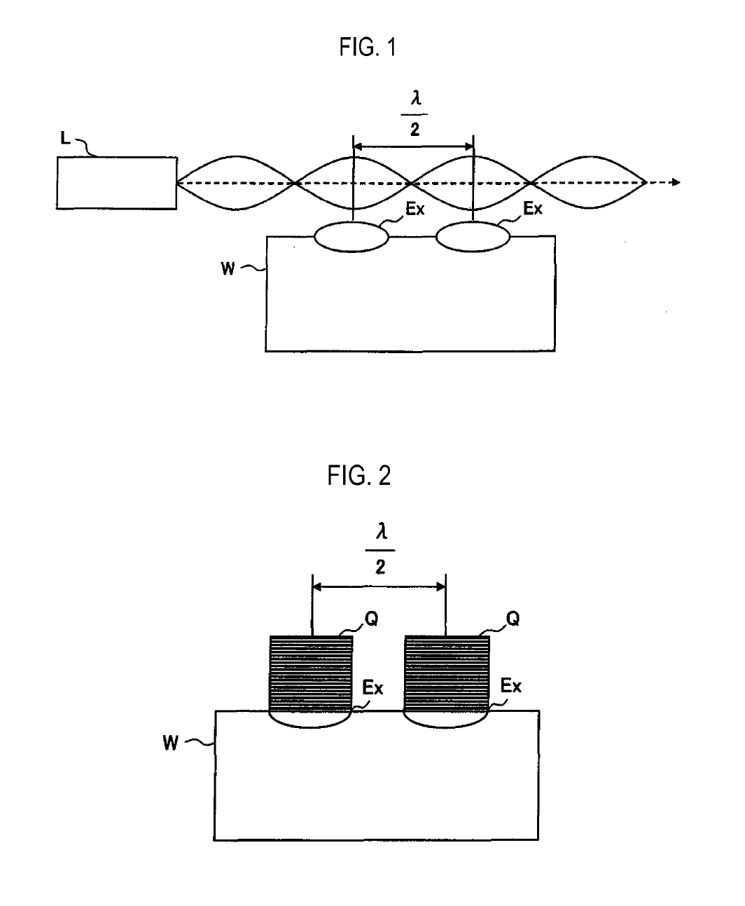

First, the principle of a substrate surface excitation process used in the quantum dot forming method of the present disclosure will be described with reference to the accompanying drawings. FIG. 1 is a view for explaining an operation of specifying quantum dot growth positions on a substrate. FIG. 2 is a view illustrating quantum dots grown in the specified positions.

In the present embodiment, the quantum dots are allowed to grow on the substrate in an SK (Stranski Krastanov) mode using the strain energy of crystals and also using the self-organizing phenomenon appearing during a crystal growth. The term “SK mode” used herein means that a two-dimensional film structure is changed to a three-dimensional island-shaped structure during the crystal growth.

For example, when a film (e.g., an In—As film) having a lattice constant differing from the lattice constant of crystals of a base film (e.g., a Ga—As film) formed on the substrate is allowed to grow on the base film, the growing layer has a strain if the degree of lattice unconformity is 1.7% or more. Thus, the energy of a system as a whole becomes greater. The strain energy of the system is increased in proportion to the increase of a growing film pressure. An SK mode occurs just when the thickness of the film becomes greater than a critical film thickness. As a consequence, the growing film is changed to an island-shaped structure and this portion grows as quantum dots. In this film growing process, it is possible to use, e.g., a molecular beam epitaxy (MBE), a metal organic chemical vapor deposition (MOCVD) or a metal organic vapor phase epitaxy (MOVPE).

Since the self-organizing phenomenon appearing during a crystal growth is used in forming the quantum dots by the SK mode, there is a problem that it is extremely difficult to control the formation positions of the quantum dots.

In view of this, many methods have been developed to control the positions of quantum dots. However, a technique of accurately forming quantum dots in desired positions with a nano order interval is not available thus far. There is known, e.g., a technique of controlling the positions of quantum dots by applying a surface wave (elastic wave) on a substrate and forming quantum dots in the spots corresponding to the wavelength of the elastic wave. In this technique, however, the propagation of the elastic wave varies with the structure of a substrate surface. Therefore, there is a possibility that the quantum dots actually formed may deviate from desired positions, thereby causing variations in the formation positions of the quantum dots.

In case of a standing wave of a laser beam, there is no change in the positions of troughs where the energy becomes greatest and in the positions of nodes where the energy becomes smallest. In the present disclosure, a laser beam having this property is irradiated from one side of a substrate along the surface of the substrate, whereby the substrate surface is partially excited at a nano order interval using the troughs of the standing wave of the laser beam. This makes it possible to allow quantum dots to grow only in the excited spots, thereby controlling the positions of the quantum dots with increased accuracy.

In the present disclosure, the laser beam is not brought into direct contact with the substrate but is irradiated to graze along the substrate surface from one side of the substrate. This makes it possible to excite the substrate surface without causing any elastic wave motion in the substrate itself. In the present disclosure, therefore, it is possible to form quantum dots in desired positions regardless of the substrate surface structure by effectively using the property of a laser beam.

For example, as shown in FIG. 1, if a laser beam emitting from a laser beam source L is irradiated from one side of a substrate W along the surface of the substrate W before formation of quantum dots, it is possible to excite only the spots of the substrate surface closest to the troughs of the standing wave of the laser beam. Since the troughs of the standing wave of the laser beam exist at an interval of one half (λ/2) of the wavelength of the standing wave, the substrate surface can be excited at the same interval as the troughs of the standing wave. Hereinafter, the process of exciting the substrate surface with the laser beam in this manner will be referred to as a substrate surface excitation process.

Thereafter, as shown in FIG. 2, if a film having a lattice constant differing from that of a base film forming the substrate surface is allowed to grow by performing a film formation process in the SK mode, three-dimensional island-shaped structures are formed only on the excited spots so that quantum dots Q can grow. As a result, the quantum dots Q are formed at the interval of the troughs of the standing wave of the laser beam, namely at a nano order interval of one half (λ/2) of the wavelength of the standing wave of the laser beam.

In the substrate surface excitation process mentioned above, the laser beam is irradiated from one side of the substrate in a direction parallel to the substrate surface. Consequently, if the troughs of the standing wave of the laser beam having the greatest energy make direct contact with the substrate surface, only the contacted spots can be partially excited by the energy of the troughs of the standing wave. Even if the troughs of the standing wave do not make contact with the substrate surface, it is still possible to partially excite the substrate surface with the radiant heat of the troughs of the standing wave.

### (Configuration Example of Substrate Surface Excitation Unit)

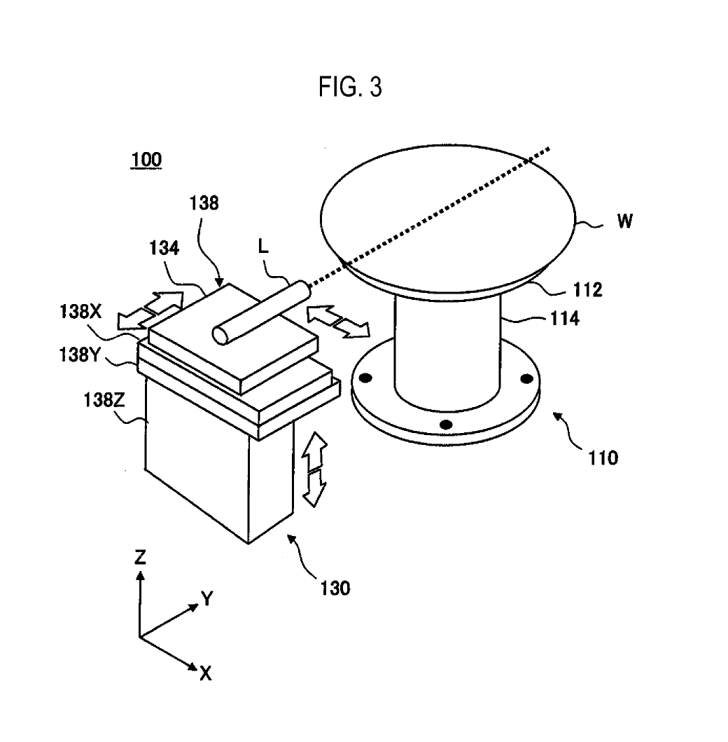

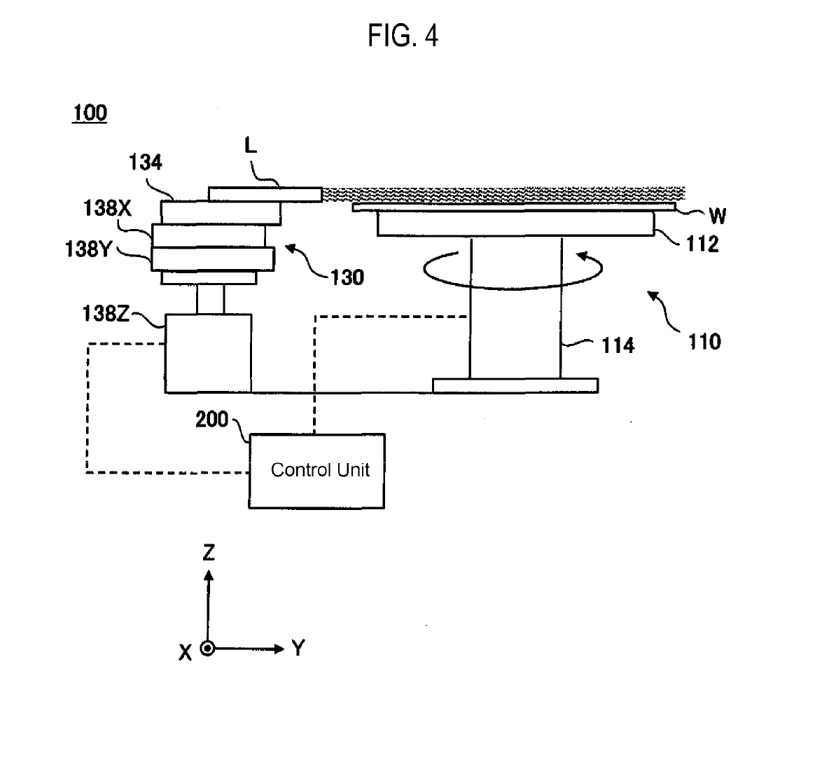

A substrate surface excitation unit (substrate surface excitation process unit) for performing the substrate surface excitation process using a laser beam will now be described with reference to the drawings. FIG. 3 is a perspective view showing one configuration example of a substrate surface excitation unit 100 and FIG. 4 is a cross-sectional view thereof. In the present embodiment, description will be made of when the substrate surface excitation process using a laser beam is performed with respect to a base film formed on a substrate W which is a semiconductor wafer.

As shown in FIGS. 3 and 4, the substrate surface excitation unit 100 includes a stage unit 110 having a rotatable stage 112 for supporting a substrate W and a laser unit 130 arranged near the stage unit 110. The stage 112 is formed into, e.g., a disk shape, as shown in FIG. 3. The substrate W is mounted on a top mounting surface of the stage 112. The stage 112 is installed to, e.g., the bottom surface of a processing chamber, through a support post 114 by fastening members such as bolts.

In the stage 112, a motor (e.g., a stepping motor) is installed within the support post 114. The stage 112 is rotated by driving the motor. The stage 112 is provided with a holding mechanism, e.g., a vacuum chuck, for holding the substrate W on the mounting surface. By keeping the substrate W held on the mounting surface with the holding mechanism, it is possible to prevent the substrate W from slipping out of the mounting surface during rotation of the stage 112. The holding mechanism is not limited to the vacuum chuck mentioned above but may be a clamp mechanism, an electrostatic chuck or other mechanisms capable of holding the substrate W in place.

As shown in FIGS. 3 and 4, the laser unit 130 includes a laser drive mechanism 138 capable of driving the laser beam source L not only in the vertical direction but also in the horizontal direction. The laser beam source L is configured from, e.g., a semiconductor laser that can irradiate a laser beam having a nano-sized standing wave. The laser beam source L is installed on the laser drive mechanism 138 through a base 134. The laser drive mechanism 138 includes a vertical drive unit for driving the base 134 in the vertical direction (Z-direction) and a horizontal drive unit for driving the base 134 in the horizontal direction. More specifically, the vertical drive unit is configured from a Z-direction drive unit 138Z. The horizontal drive unit is configured from an X-direction drive unit 138X for driving the base 134 in the X-direction and a Y-direction drive unit 138Y for driving the base 134 in the Y-direction.

By driving the laser beam source L with the X-direction drive unit 138X of the laser drive mechanism 138, it is possible to scan the laser beam over the entire surface of the substrate W. By driving the laser beam source L with the Z-direction drive unit 138Z, it is possible to adjust the vertical position of the laser beam in alignment with the height of the surface of the substrate W. By driving the laser beam source L with the Y-direction drive unit 138Y, it is possible to adjust the horizontal position of the laser beam in alignment with the diameter of the substrate W.

As shown in FIG. 4, the stage unit 110 is connected to a control unit. The rotation of the stage 112 and the operation of the laser drive mechanism 138 are controlled by control signals issuing from the control unit 200.

### (Specific Example of Substrate Surface Excitation Process)

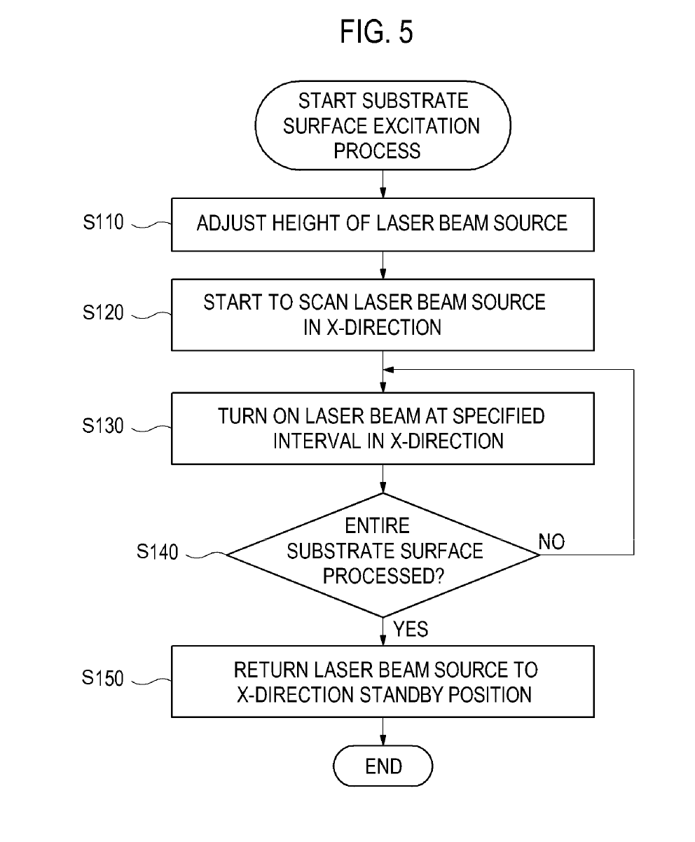

Next, a substrate surface excitation process using the substrate surface excitation unit 100 of the above configuration will be described with reference to the drawings. Based on a specified program, the control unit 200 controls the operation of the substrate surface excitation unit 100 to perform a substrate surface excitation process. FIG. 5 is a flowchart illustrating one specific example of the substrate surface excitation process.

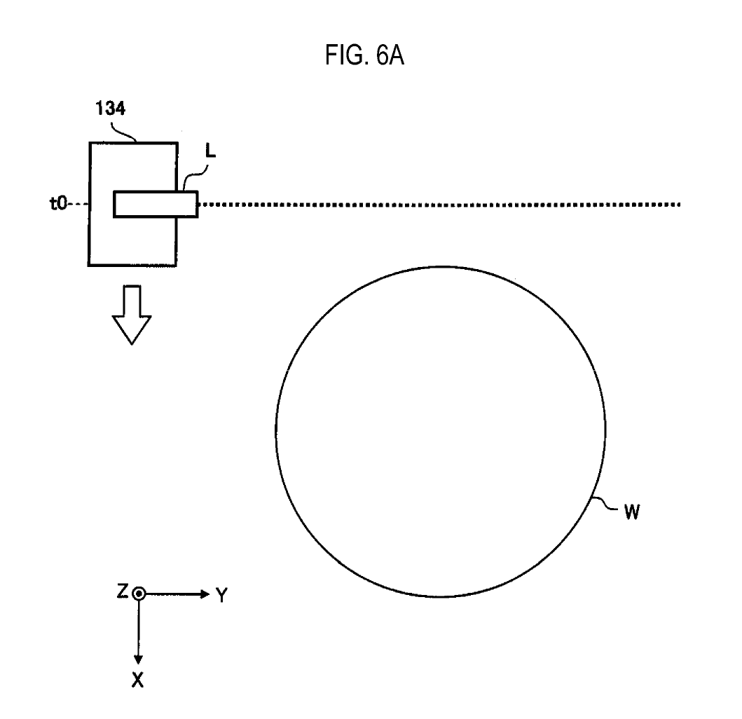

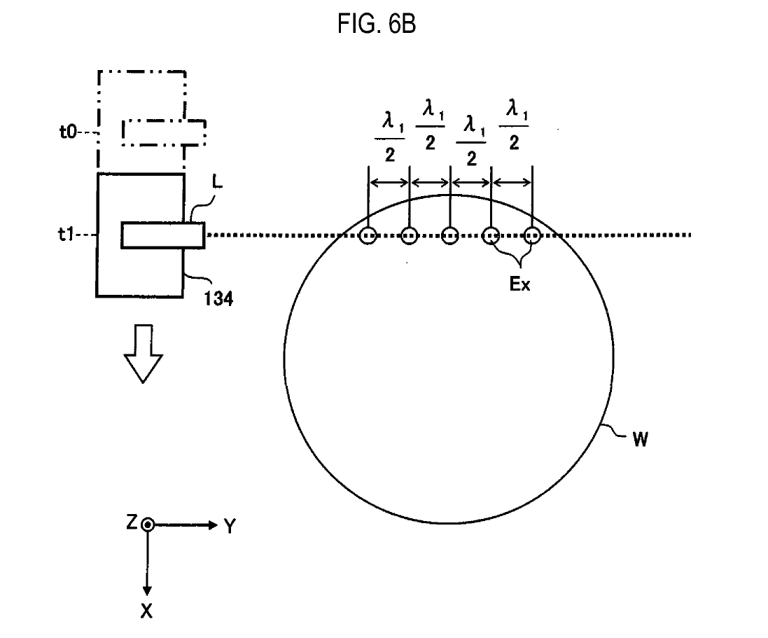

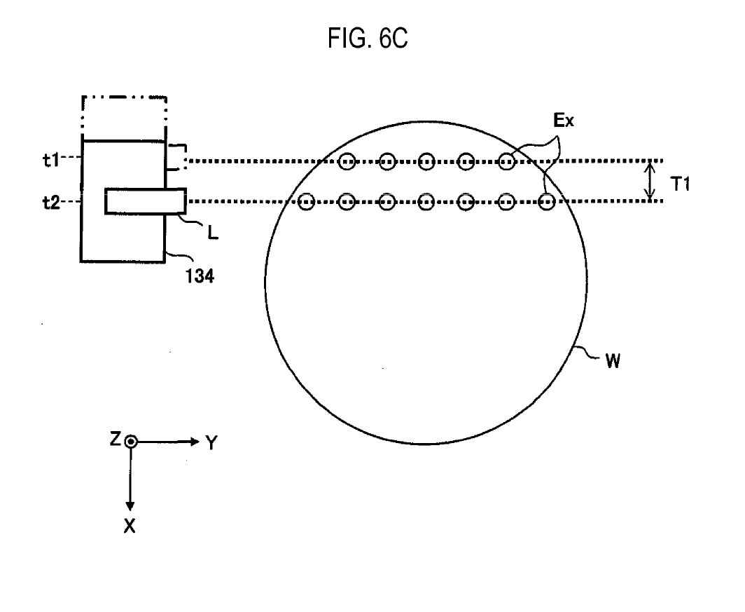

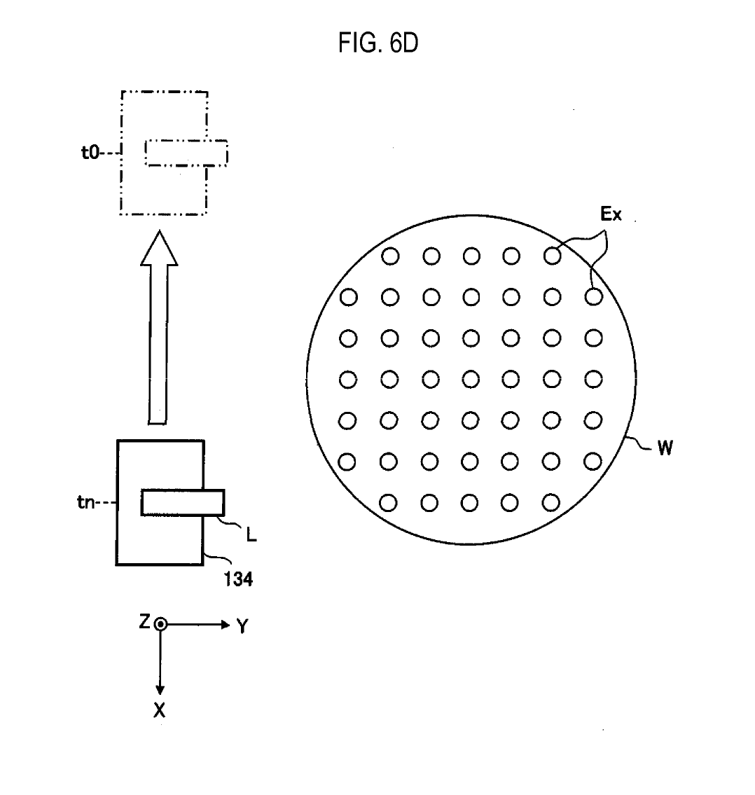

FIGS. 6A to 6D are views for explaining the action of the laser beam during the course of performing the substrate surface excitation process. In FIGS. 6A to 6D, the laser beam source L is respectively located in positions t0, t1, t2 and tn. FIGS. 6A to 6D are views obtained by seeing the substrate surface excitation unit 100 from above. Components of the laser unit 130 other than the base 134 and the laser beam source L are omitted in FIGS. 6A through 6D.

The substrate surface excitation process will be described by taking as an example a case where the spots for formation of quantum dots Q are excited by the substrate surface excitation unit 100 before forming the quantum dots Q on a base film of a substrate surface in the SK mode.

First, a substrate W having a base film formed thereon is brought onto the stage 112 of the stage unit 110 by a conveying arm not shown in the drawings. Then, the substrate surface excitation process is performed pursuant to the flowchart shown in FIG. 5. In the substrate surface excitation process, the height (Z-direction position) of the laser beam source L is first adjusted in step S110. More specifically, the laser beam is turned on and the Z-direction drive unit 138Z is driven in such a state that the laser beam source L is located in a X-direction standby position t0 spaced apart from the outer edge portion of the substrate W as shown in FIG. 6A. As a result, the height of the laser beam source L is adjusted so that the laser beam can be irradiated along the surface of the substrate W.

In step S120, the laser beam is turned off and the laser beam source L begins to scan in the X-direction at a constant speed. In step S130, the laser beam is turned on at a specified interval T1 from the time when the laser beam source L arrives at an excitation start position t1 on the substrate W. More specifically, if the laser beam source L arrives at the excitation start position t1 as shown in FIG. 6B, the laser beam is turned on only for a predetermined irradiation time. This excites only the spots Ex corresponding to the troughs of the standing wave of the laser beam in the X-direction excitation start position t1 of the substrate surface. Thus, the interval of the excited spots Ex in the Y-direction (the irradiation direction of the laser beam) is equal to λ₁/2, one half of the wavelength of the standing wave of the laser beam.

Subsequently, the laser beam source L is scanned in the X-direction with the laser beam kept turned off. When the laser beam source L arrives at a next position t2 as shown in FIG. 6C, the laser beam is turned on only for the afore-mentioned irradiation time. This excites only the spots corresponding to the troughs of the standing wave of the laser beam at next position t2 of the substrate surface in the X-direction. The interval of the excited spots Ex in the Y-direction (the irradiation direction of the laser beam) is equal to λ₁/2, one half of the wavelength of the standing wave of the laser beam. Thereafter, the laser beam is repeatedly turned on for the afore-mentioned irradiation time at the specified interval T1 while scanning the laser beam source L in the X-direction.

In step S140, it is determined whether the excitation process is finished with respect to the entire substrate surface. More specifically, a determination is made as to whether the substrate surface excitation is completed up to an excitation end position tn on the substrate W. If it is determined in step S140 that the excitation process is finished with respect to the entire substrate surface, in step S150, the laser beam is turned off and the laser beam source L is returned to the standby position t0 in the X-direction as shown in FIG. 6D. Then, a series of steps in the substrate surface excitation process is completed.

In this manner, the surface of the substrate W can be excited from the excitation start position t1 to the excitation end position tn. Through a film growing process subsequently performed in the SK mode, quantum dots Q are formed only in the excited spots Ex.

The X-directional interval of the excited spots Ex is equal to the specified interval T1 at which the laser beam is irradiated. The Y-directional interval of the excited spots Ex is equal to λ₁/2, one half of the wavelength of the standing wave of the laser beam. Accordingly, it is possible to readily control the X-directional and Y-directional intervals of the quantum dots Q to be formed subsequently.

In other words, the X-directional interval of the excited spots Ex can be simply controlled by merely changing the specified interval T1, i.e., the on-timing of the laser beam. This makes it possible to control the X-directional interval of the quantum dots Q to be formed subsequently. In this manner, the X-directional interval of the quantum dots Q can be controlled in a nano order dimension depending on the on-timing of the laser beam.

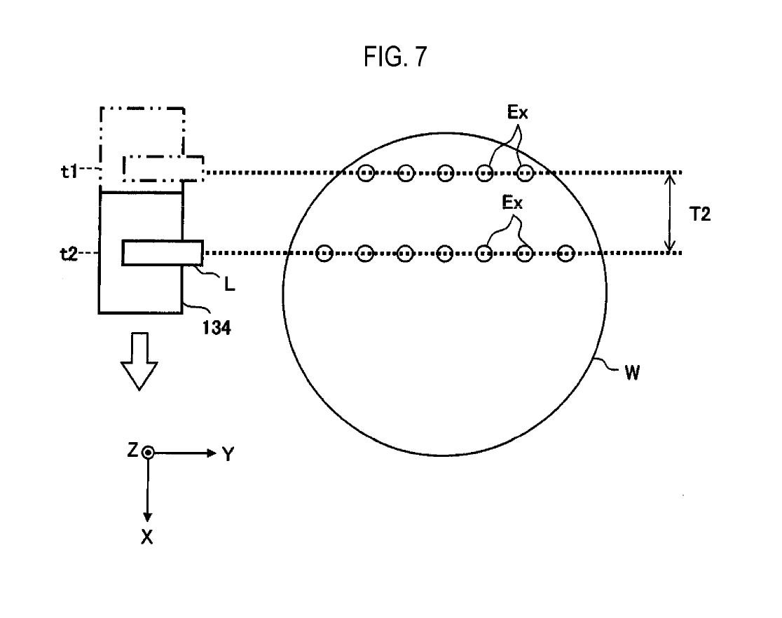

More specifically, the X-directional interval of the excited spots Ex can be shortened by shortening the specified interval T1 at which the laser beam is turned on. It is therefore possible to form the quantum dots Q at a shortened X-directional interval. On the contrary, the X-directional interval of the excited spots Ex can be lengthened by lengthening the specified interval T1 at which the laser beam is turned on. It is therefore possible to form the quantum dots Q at a lengthened X-directional interval. For example, FIG. 7 illustrates when the substrate surface excitation process is performed at an interval T2 greater than the specified interval T1 at which the laser beam is turned on.

As set forth above, the X-directional interval of the excited spots Ex can be adjusted by intermittently irradiating the laser beam at a specified interval. The method of intermittently irradiating the laser beam is not limited to turning on/off the laser beam in the afore-mentioned manner. As an alternate example, a shutter capable of interrupting the laser beam may be provided to repeat interruption and non-interruption of the laser beam.

The Y-directional (laser beam irradiation direction) interval of the excited spots Ex can be simply controlled by merely changing the wavelength λ₁ of the standing wave of the laser beam. This makes it possible to control the Y-directional interval λ₁/2 of the quantum dots Q to be formed subsequently. In this manner, the Y-directional interval of the quantum dots Q can be controlled in a nano order dimension by changing the wavelength of the laser beam.

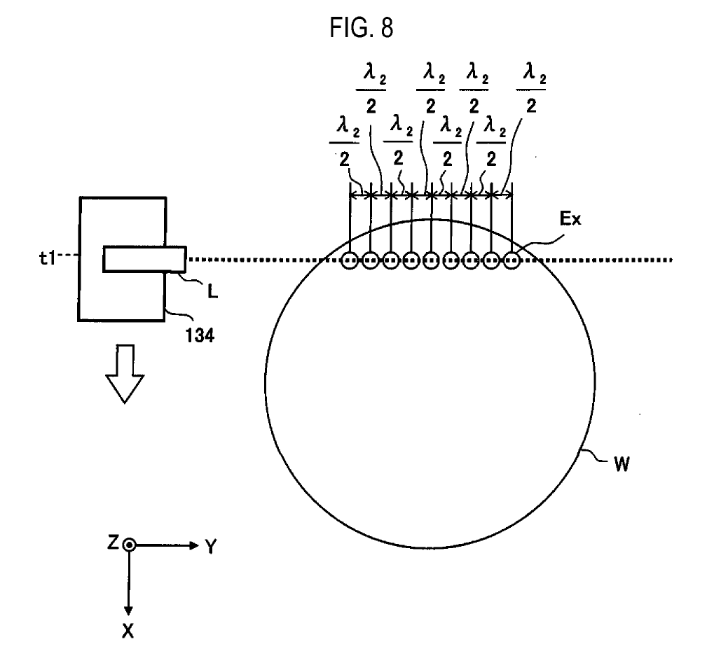

More specifically, the Y-directional interval of the excited spots Ex can be shortened by shortening the wavelength of the laser beam. It is therefore possible to form the quantum dots Q at a shortened Y-directional interval. On the contrary, the Y-directional interval of the excited spots Ex can be lengthened by lengthening the wavelength of the laser beam. It is therefore possible to form the quantum dots Q at a lengthened Y-directional interval. For example, FIG. 8 illustrates when the substrate surface excitation process is performed by setting the wavelength of the laser beam equal to λ₂ which is shorter than λ₁. In this case, the Y-directional interval of the quantum dots Q becomes equal to λ₂/2, one half of the wavelength of the laser beam.

In the embodiment described above, the laser beam is turned on and off while scanning the laser beam source L in the X-direction. Therefore, the Y-directional length of the excited spots Ex can be adjusted by changing the irradiation time when the laser beam is turned on. This makes it possible to control the size of the quantum dots Q formed in the excited spots Ex.

The method of exciting the substrate surface is not limited to when the laser beam is turned on and off at a specified interval while continuously scanning the laser beam source L in the X-direction as in the foregoing embodiment. Alternatively, the laser beam source L may be stopped at a specified interval. More specifically, the laser beam source L is scanned from the standby position t0 in the X-direction and is stopped in the excitation start position t1 so that the laser beam is turned on for a specified irradiation time. Thereafter, the laser beam source L is scanned toward the excitation end position to and is stopped at a specified interval. In each of the stopped positions, the laser beam is turned on for a specified irradiation time. In this case, the laser beam source L is kept stopped during irradiation of the laser beam. Therefore, the amount of energy applied on the same excited spots Ex can be adjusted by changing the irradiation time of the laser beam.

After forming the excited spots Ex as shown in FIG. 6D by performing the substrate surface excitation process once, the stage 112 is turned to rotate the substrate W by, e.g., 90 degrees. In this state, the substrate surface excitation process is performed again while changing the wavelength and irradiation time of the laser beam, whereby additional excited spots Ex can be formed between the excited spots Ex formed in the first substrate surface excitation process. This makes it possible to densely form the excited spots Ex. The rotation angle of the substrate W is not limited to 90 degrees. The excited spots Ex can be formed in desired positions by freely changing the angle of the substrate W through the rotation of the stage 112. This makes it possible to form quantum dots Q in desired positions on the substrate W.

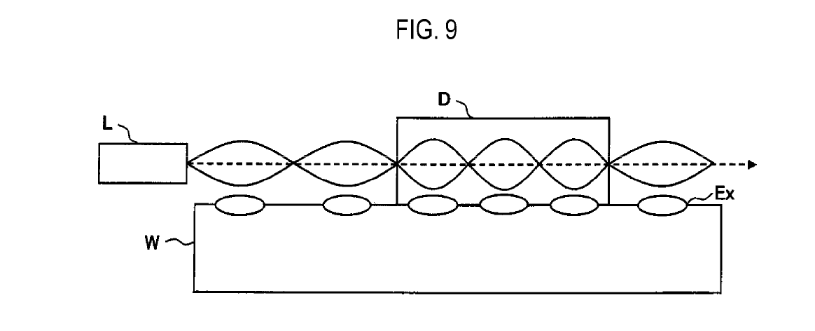

By mounting a dielectric on the substrate W, it is possible to partially change the wavelength of the laser beam. More specifically, if a dielectric D is placed on the substrate W as shown in FIG. 9 so that the laser beam can pass therethrough, the wavelength of the laser beam is changed within the dielectric D. Thus, the X-directional interval of the excited spots Ex are changed in the area where the dielectric D is placed. Use of the dielectric D makes it possible to form quantum dots Q at a different interval only in a desired area.

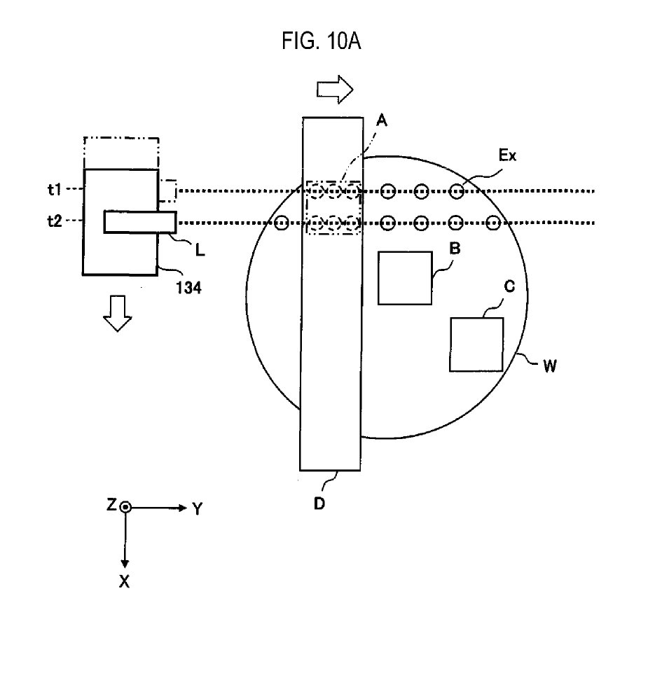

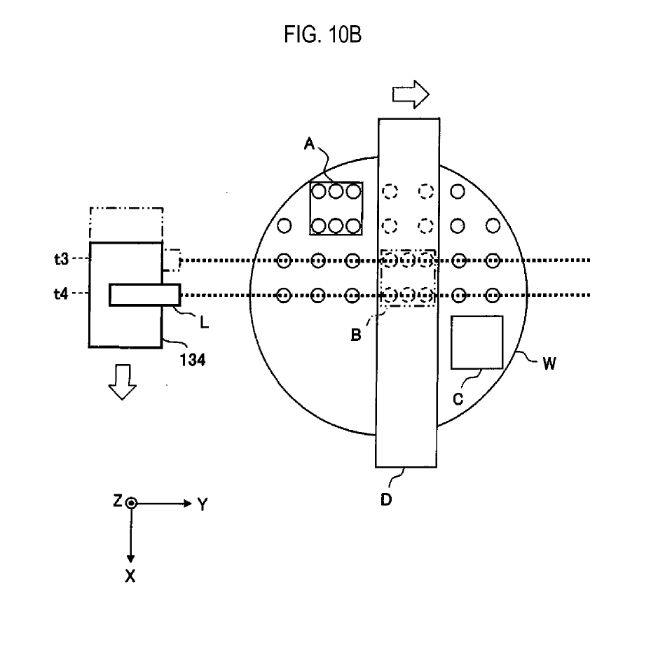

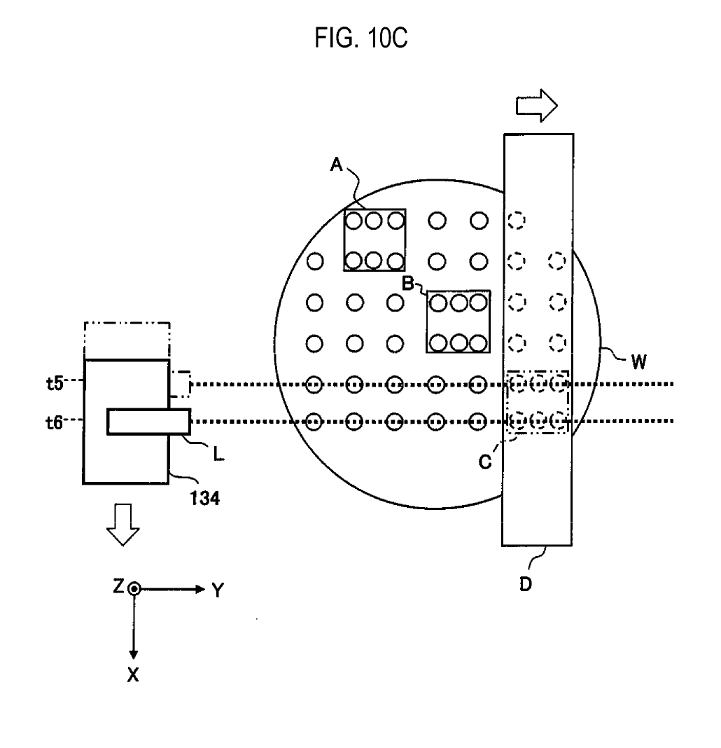

A substrate surface excitation process for forming quantum dots Q at a different X-directional interval only in a specific area using the dielectric D will now be described with reference to the drawings. FIGS. 10A, 10B and 10C are views for explaining the action of the dielectric D. Description will be made herein by taking as an example a case where quantum dots Q are formed more densely in specific areas A, B and C on the substrate W than in other areas.

First, the laser beam source L is scanned in the X-direction in a state that the dielectric D is mounted on the specific area A. Then, the laser beam is turned on at the timings of t1 and t2 as shown in FIG. 10A so that the laser beam can pass through the dielectric D. At this time, the wavelength of the laser beam becomes shorter when it is inside of the dielectric D than when it is outside of the dielectric. Accordingly, excited spots Ex are formed more densely in the specific area A than in other areas in the Y-direction (laser beam irradiation direction).

Next, the laser beam source L is scanned in the X-direction when the dielectric D is mounted on the specific area B. Then, the laser beam is turned on at t3 and t4 as shown in FIG. 10B. As in the case shown in FIG. 10A, excited spots Ex are formed more densely in the specific area B than in other areas in the Y-direction (laser beam irradiation direction).

Subsequently, the laser beam source L is scanned in the X-direction when the dielectric D is mounted on the specific area C. Then, the laser beam is turned on at t5 and t6 as shown in FIG. 10C. As in the case shown in FIG. 10A, excited spots Ex are formed more densely in the specific area C than in other areas in the Y-direction (laser beam irradiation direction).

As set forth above, by shifting the dielectric D in the Y-direction and irradiating the dielectric on the substrate W at a specified time when the laser beam source L is scanned in the X-direction, it is possible to form quantum dots Q at a different X-directional intervals only in the specific areas. The wavelength of the laser beam within the dielectric D can be adjusted by changing the dielectric constant of the dielectric D. Accordingly, the Y-directional (laser beam irradiation direction) interval of the quantum dots Q within the dielectric D can be adjusted by replacing the dielectric D with another dielectric having a different dielectric constant.

In the foregoing embodiment, description has been made when desired spots are excited by scanning the substrate surface with a single laser beam. However, the present disclosure is not limited thereto. Alternatively, desired spots may be excited by scanning the substrate surface with a plurality of laser beams.

### (Modified Example of Substrate Surface Excitation Unit)

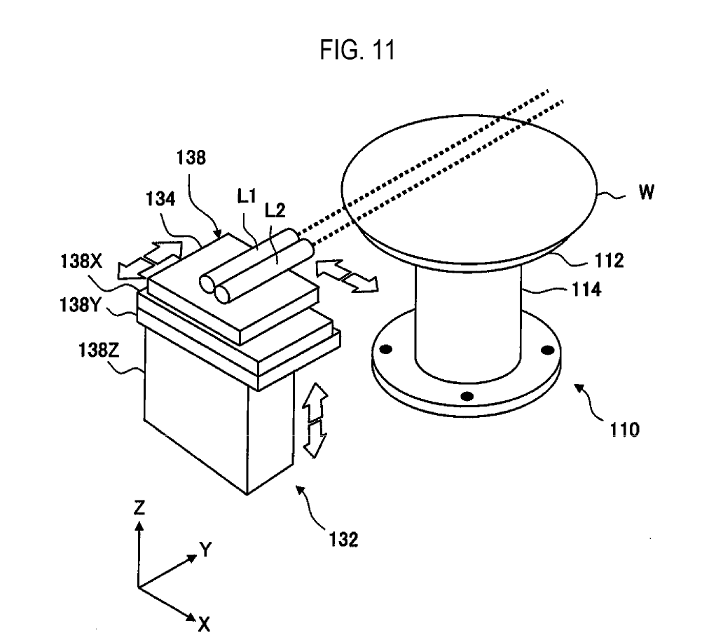

A modified example of the substrate surface excitation unit 100 capable of scanning the substrate surface with two laser beams will now be described with reference to the drawings. FIG. 11 is a perspective view showing a modified example of the substrate surface excitation unit 100. The substrate surface excitation unit 100 shown in FIG. 11 includes a laser unit 132 capable of irradiating two laser beams. The laser unit 132 includes a base 134 and two laser beam sources L1 and L2 installed on the base 134. Other components remain the same as those shown in FIG. 3 and, therefore, will not be described in detail.

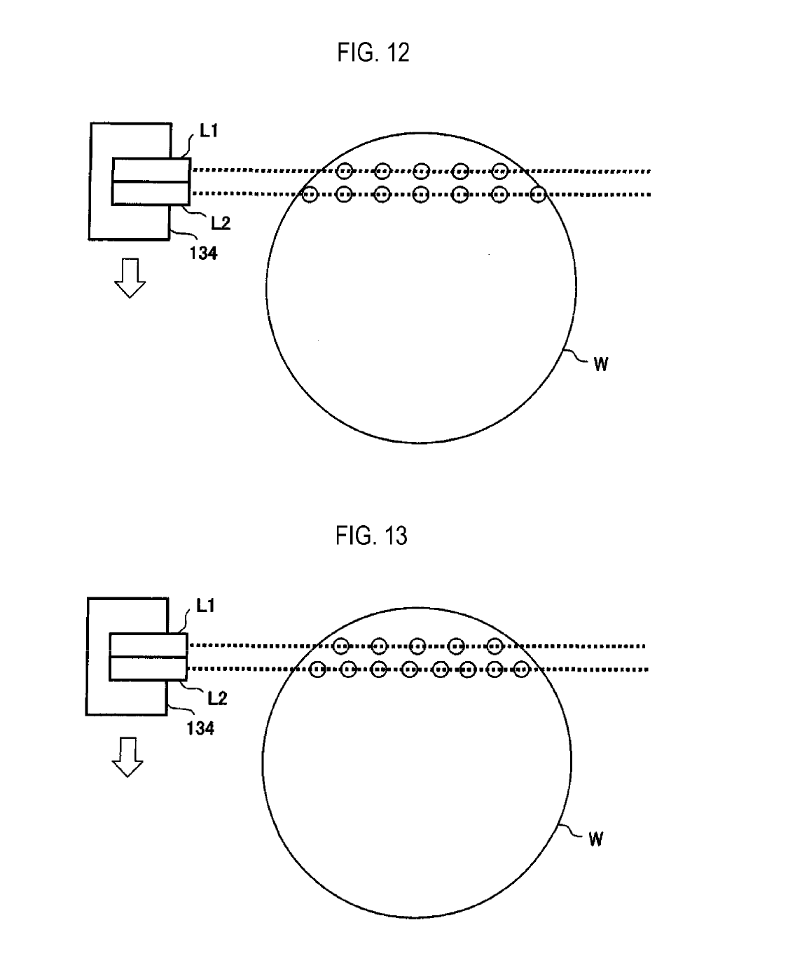

The laser beams emitted from the laser beam sources L1 and L2 may have either the same wavelength or different wavelengths. When irradiating the laser beams having the same wavelength, two Y-directional lines can be simultaneously excited by simultaneously irradiating the laser beams as shown in FIG. 12. This makes it possible to increase the speed of the substrate surface excitation process. When irradiating the laser beams having different wavelengths, quantum dots Q can be formed at different X-directional intervals in the Y-directional odd number line and even number line as shown in FIG. 13.

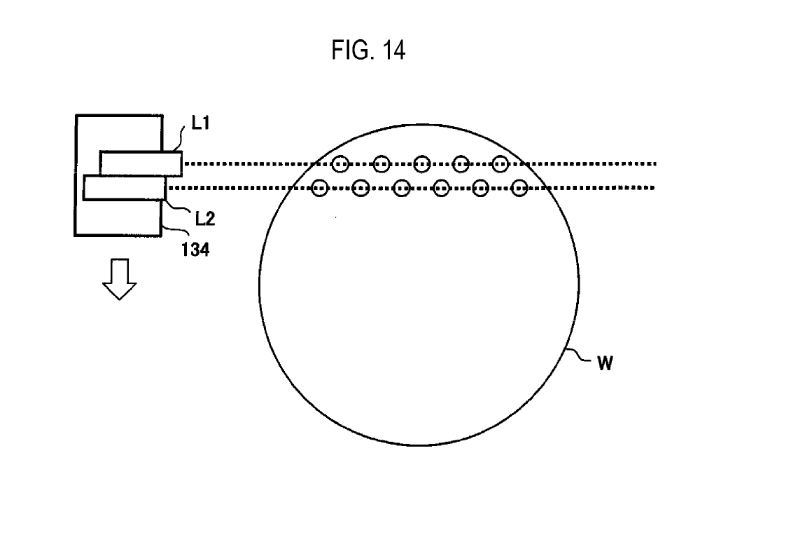

As shown in FIG. 14, the laser beam sources L1 and L2 may be installed on the base 134 in dislocated positions. This makes it possible to form quantum dots Q that are staggered at a specified interval along the Y-directional odd number line and even number line.

By scanning the substrate surface with the plurality of laser beams, it is possible not only to increase the processing speed but also to finely control the formation positions of the quantum dots Q. While FIG. 14 illustrates the case when the substrate surface excitation process is performed by irradiating two laser beams, the present disclosure is not limited thereto. Alternatively, the substrate surface excitation process may be performed by irradiating three or more laser beams. In addition, the plurality of laser beams may be irradiated at different times instead of being simultaneously irradiated. For example, when laser beams having different wavelengths are in use, the substrate surface can be excited at a desired interval by turning on, if necessary, either one of the laser beams.

If a film is allowed to grow, in the SK mode, on the substrate W subjected to the afore-mentioned substrate surface excitation process, quantum dots Q as three-dimensional island-shaped structures are formed only in the excited spots Ex as shown in FIG. 6D. With the present embodiment, therefore, the formation positions of the quantum dots Q can be controlled by an extremely simple control method in which the laser beam is turned on and off while allowing the laser beam source to scan the substrate surface. Since no vibration is generated in the substrate surface, it is always possible to form quantum dots Q in desired positions even on the substrates having different surface structures.

(Substrate Processing Apparatus Applicable with Substrate Surface Excitation Unit)

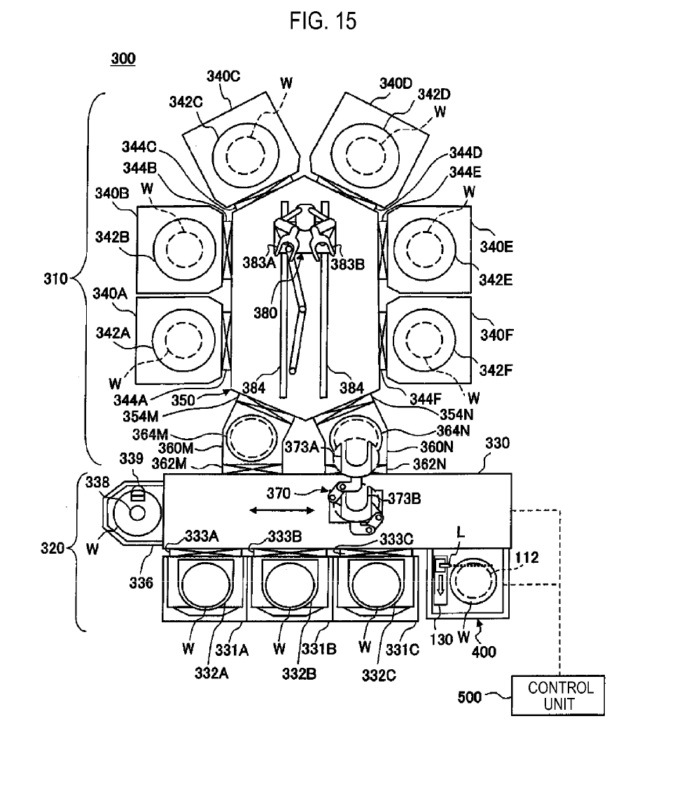

Next, one example of a substrate processing apparatus for use with the substrate surface excitation unit 100 will be described with reference to the drawings. FIG. 15 is a cross-sectional view schematically showing a configuration of a substrate processing apparatus. The substrate processing apparatus 300 includes a processing unit 310 provided with a plurality of processing chambers where a film is allowed to grow on a substrate W in the SK mode for formation of quantum dots Q and a conveying unit 320 provided with a conveying chamber 330 where the substrate W is loaded to or unloaded from the processing unit 310.

First, a description will be given on the configuration of the conveying unit 320. The conveying unit 320 includes a conveying chamber 330 where a plurality of (e.g., twenty five) substrates W held within a cassette container 332 is carried into or out of the substrate processing apparatus 300. Within the conveying chamber 330, there are provided, e.g., three cassette tables 331A to 331C by way of gate valves 333A to 333C. Cassette containers 332A to 332C can be respectively set on the cassette tables 331A to 331C.

Also provided within the conveying chamber 330 is a substrate surface excitation chamber 400 for performing the substrate surface excitation process described above. A substrate surface excitation unit (substrate surface excitation process unit) 100 is arranged within the substrate surface excitation chamber 400. The configuration of the substrate surface excitation unit 100 is the same as shown in FIG. 3 and, therefore, will not be described in detail.

A pre-alignment chamber (orientor) 336 for aligning the substrates W is installed in the conveying chamber 330. The pre-alignment chamber 336 includes, e.g., a stage 338 rotatably arranged within the pre-alignment chamber 336 and an optical sensor 339 for optically detecting the peripheral edge portions of the substrates W placed on the stage 338. The substrates W are rotated by the stage 338. Orientation flats or orientation notches formed in the peripheral edge portions of the substrates W are detected by the optical sensor 339 to perform alignment of the substrates W.

Within the conveying chamber 330, there is provided a conveying robot 370 capable of sliding along the longitudinal direction of the conveying chamber 330 (along the direction indicated by an arrow in FIG. 15). The conveying robot 370 includes, e.g., conveying arms 373A and 373B for holding and conveying the substrates W. The conveying arms 373A and 373B are configured to make bending and stretching movements, up-down movements and swiveling movements. The conveying arms 373A and 373B is capable of loading and unloading the substrates W into and from the cassette containers 332A to 332C, the pre-alignment chamber 336, the substrate surface excitation chamber 400, and the load lock chambers 360M and 360N to be described later. Since the conveying robot 370 is provided with the two conveying arms 373A and 373B, the conveying robot 370 can use the conveying arms 373A and 373B to perform the loading and unloading operations of the substrates W with respect to, e.g., the load lock chambers 360M and 360N, the pre-alignment chamber 336, and the substrate surface excitation chamber 400 so that the processed substrates W and the unprocessed substrates W can be exchanged with each other.

Next, a description will be given on the configuration of the processing unit 310. As can be seen in FIG. 15, the processing unit 310 is of, e.g., a cluster tool type. In other words, the processing unit 310 includes a common conveying chamber 350 formed into a polygonal shape (e.g., a hexagonal shape) and a plurality of (e.g., six) processing chambers 340A to 340F arranged around the common conveying chamber 350 to perform specified processes with respect to the substrates W. The processing chambers 340A to 340F are connected to the common conveying chamber 350 through gate valves 344A to 344F.

The processing chambers 340A to 340F are respectively provided with stages 342 (342A to 342F) for supporting the substrates W. Each of the processing chambers 340A to 340F includes a quantum dot formation process unit for, based on the process recipes pre-stored in a storage medium of a control unit 500, performing the film formation process on the substrates W placed on the stages 342, e.g., in the SK mode for formation of quantum dots Q. Each of the processing chambers 340A to 340F is designed to perform a process in which quantum dots Q are formed by the quantum dot formation process unit in the excited spots Ex of the substrate subjected to the substrate surface excitation process through the growth of a film having a lattice constant differing from that of a base film formed on the substrate surface.

When the film formation process is performed by, e.g., a molecular beam epitaxy (MBE), the quantum dot formation process unit includes an exhaust unit such as a vacuum pump for depressurizing the inside of the processing chambers 340A to 340F to a predetermined vacuum pressure, a heating mechanism for heating the substrate, a raw material supply source for supplying a thin-film raw material on the substrate surface and a molecular beam source (e.g., a molecular beam cell or an electron gun) as a raw material vaporization source for irradiating a molecular beam toward the substrate surface.

This makes it possible to configure each of the processing chambers 340A to 340F as an MBE processing chamber in which a thin-film raw material is heated under a high vacuum pressure and deposited on the substrate surface to have quantum dots Q grow on the substrate surface. The MBE processing chamber may have the same configuration as employed in a conventional MBE apparatus.

The processing chamber for performing a film formation process to form quantum dots Q is not limited to the MBE processing chamber. When the film formation process is performed by, e.g., a metal organic chemical vapor deposition (MOCVD), the quantum dot formation process unit includes an exhaust unit such as a vacuum pump for depressurizing the inside of each of the processing chambers 340A to 340F to a predetermined vacuum pressure, a heating mechanism for heating the substrate and a raw material supply source for vaporizing a thin-film raw material and supplying the vaporized raw material on the substrate surface. In this case, if the film formation is performed by using plasma, an electrode for applying high-frequency power to generate plasma may be further provided.

This makes it possible to configure each of the processing chambers 340A to 340F as an MOCVD processing chamber in which quantum dots Q are allowed to grow by causing a raw material to react at an elevated temperature and forming a film on the substrate surface by a CVD process. The MOCVD processing chamber may have the same configuration as employed in a conventional MOCVD apparatus.

At least one of the processing chambers 340A to 340F may be configured as the processing chamber for performing a film formation process to form quantum dots Q. The remaining processing chambers may be configured as processing chambers for performing other kinds of processes such as etching and heating. The number of the processing chambers 340 is not limited to the one shown in FIG. 15.

The load lock chambers 360M and 360N for exchanging the substrates W with the conveying chamber 330 are installed around the common conveying chamber 350. The load lock chambers 360M and 360N temporarily hold the substrates W on delivery tables 364M and 364N arranged therein and pass, after pressure adjustment, the substrates W between the common conveying chamber 350 kept at a vacuum pressure and the conveying chamber 330 kept at the atmospheric pressure. In order to assure air-tightness, the load lock chambers 360M and 360N are connected to the common conveying chamber 350 through gate valves 354M and 354N and to the conveying chamber 330 through gate valves 362M and 362N.

Within the common conveying chamber 350, there is provided a conveying robot 380 capable of sliding along guide rails 384 installed in the longitudinal direction of the common conveying chamber 350. The conveying robot 380 includes, e.g., conveying arms 383A and 383B for holding and conveying the substrates W. The conveying arms 383A and 383B are configured to make bending and stretching movements, up-down movements and swiveling movements. The conveying arms 383A and 383B are capable of loading and unloading the substrates W into and from the processing chambers 340A to 340F and the load lock chambers 360M and 360N.

For example, the conveying robot 380 is slid toward the base end of the common conveying chamber 350 to perform the loading and unloading operations of the substrates W with respect to the load lock chambers 360M and 360N and the processing chambers 340A through 340F. The conveying robot 380 is slid toward the tip end of the common conveying chamber 350 to perform the loading and unloading operations of the substrates W with respect to the four processing chambers 340B to 340E. Since the conveying robot 380 is provided with the two conveying arms 383A and 383B, the conveying robot 380 can use the conveying arms 383A and 383B to perform the loading and unloading operations of the substrates W with respect to, e.g., the processing chambers 340A to 340F and the load lock chambers 360M and 360N so that the processed substrates W and the unprocessed substrates W are exchanged with each other.

The substrate processing apparatus 300 includes a control unit 500 for controlling the operations of the substrate processing apparatus 300 as a whole, including the operations of the conveying robots 370 and 380, the gate valves 333, 344, 354 and 362, the pre-alignment chamber 336 and the substrate surface excitation chamber 400. The control unit 500 includes, e.g., a CPU forming a main body of the control unit 500, a ROM for storing data needed for the CPU to perform processing, a RAM having memory areas used for various kinds of data processing performed by the CPU, a storage means such as a hard disk drive (HDD) or a memory for storing various kinds of programs and data needed for the CPU to control the respective units, a liquid crystal display for displaying an operation screen, a selection screen and other screens, an input/output means through which an operator can input and edit various kinds of data such as process recipes and can output various kinds of data such as process recipes and process logs to a specified storage medium, and a variety of controllers for controlling the respective units of the substrate processing apparatus 300.

### (Operation of Substrate Processing Apparatus)

Next, description will be made on the operations of the substrate processing apparatus 300. The substrate processing apparatus 300 is operated by the control unit 500 using a specified program. For example, a substrate W taken out from one of the cassette containers 332A to 332C by the conveying robot 370 is carried into the pre-alignment chamber 336 via the conveying chamber 330 and is subjected to position alignment.

The aligned substrate W is taken out from the pre-alignment chamber 336 and is carried into the substrate surface excitation chamber 400 where the substrate surface excitation process for the substrate W is performed by a laser beam (a substrate surface excitation step). Thus, excited spots Ex are formed in desired positions on a substrate surface (base film).

The substrate W subjected to the substrate surface excitation process is taken out from the substrate surface excitation chamber 400 and is carried into the load lock chamber 360M or 360N. At this time, if a processed substrate W subjected to all necessary processes exists within the load lock chamber 360M or 360N, the processed substrate W is first removed and then the unprocessed substrate W is carried into the load lock chamber 360M or 360N.

The substrate W carried into the load lock chamber 360M or 360N is taken out from the load lock chamber 360M or 360N by the conveying robot 380 and is loaded into one of the processing chambers 340A to 340F serving as an MBE processing chamber where a film formation process for the substrate W is performed in the SK mode to form quantum dots Q. Thus, quantum dots Q are formed in the excited spots Ex of the substrate surface (base film) (a quantum dot formation step). The processed substrate W is returned to one of the cassette containers 332A to 332C through the load lock chamber 360M or 360N and the conveying chamber 330.

With the substrate processing apparatus 300 of the present embodiment described above, it is possible to form the quantum dots Q only in the excited spots Ex by performing the substrate surface excitation process in which the desired spots of the substrate W are excited within the substrate surface excitation chamber 400 and then performing the film formation process in the SK mode within the processing chamber serving as an MBE processing chamber.

In the substrate processing apparatus 300 shown in FIG. 15, the substrate surface excitation chamber 400 including the substrate surface excitation unit 100 is installed in the conveying chamber 330 kept at atmospheric pressure. However, the present disclosure is not limited thereto. As an alternative example, the substrate surface excitation chamber 400 may be installed in the common conveying chamber 350 kept in a vacuum. In this case, one of the processing chambers 340A to 340F may be used as the substrate surface excitation chamber 400. It is not always necessary to install the substrate surface excitation unit 100 in the substrate surface excitation chamber 400 independently of other processing chambers. Alternatively, the substrate surface excitation unit 100 may be installed within one of the processing chambers 340A to 340F or within the pre-alignment chamber (orientor) 336 or the load lock chambers 360M and 360N. In this case, only the laser unit 130 may be additionally installed because the stages 342A to 342F or the delivery tables 364M and 364N are already provided within the processing chambers 340A to 340F, the pre-alignment chamber (orientor) 336 or the load lock chambers 360M and 360N.

This makes it possible to perform the substrate surface excitation process within the processing chambers 340A to 340F, the pre-alignment chamber (orientor) 336 or the load lock chambers 360M and 360N. In particular, if the laser unit 130 is installed within the processing chambers 340A to 340F serving as an MBE processing chamber or an MOCVD processing chamber in which the film formation process is performed to form the quantum dots Q, it is possible to simultaneously perform the film formation process in the SK mode while exciting the substrate surface with the laser beam.

The present disclosure described with respect to the foregoing embodiments may in some embodiments be applied to either a system composed of a plurality of devices or an apparatus composed of a single device. The present disclosure may be embodied by supplying the system or the apparatus with a medium such as a storage medium that stores a software program for realizing the functions of the foregoing embodiments and then allowing a computer (CPU or MPU) of the system or the apparatus to read out and execute the program stored in the medium such as a storage medium.

In this case, the program read out from a medium such as a storage medium realizes the functions of the foregoing embodiments. Thus, a medium such as a storage medium storing the program constitutes the present disclosure. Examples of a medium such as a storage medium for supplying the program include a floppy (registered trademark) disk, a hard disk, an optical disk, a magneto-optical disk, a CD-ROM, a CD-R, a CD-RW, a DVD-ROM, a DVD-RAM, a DVD-RW, a DVD+RW, a magnetic tape, a nonvolatile memory card and a ROM. It is also possible to download a program into a medium through a network and supply the medium to a system or an apparatus.

Not only when the functions of the foregoing embodiments are realized by executing the read-out program with a computer but also when an OS operating in a computer performs some or all actual processes pursuant to the instructions of the program to realize the functions of the foregoing embodiments is included in the present disclosure.

Also included in the present disclosure is a case when the program read out from the medium such as a storage medium is written into a memory of an extension board inserted into a computer or an extension unit connected to the computer and then a CPU of the extension board or the extension unit performs some or all actual processes pursuant to the instructions of the program to realize the functions of the foregoing embodiments.

While certain preferred embodiments of the present disclosure have been described with reference to the accompanying drawings, the present disclosure is not limited to these embodiments. It will be apparent to those skilled in the art that many different modifications or changes may be made without departing from the scope of the present disclosure defined in the claims. Needless to say, such modifications or changes shall be construed to fall within the technical scope of the present disclosure.

The present disclosure is applicable to a method of forming quantum dots on a substrate, a storage medium storing a program and a substrate processing apparatus for executing the method.

### <Aspects of Present Disclosure>

Hereinafter, aspects of the present disclosure will be additionally stated.

A first aspect of the present disclosure may provide a quantum dot forming method for forming quantum dots on a surface of a substrate, including: exciting a substrate surface with a laser beam having a standing wave which is irradiated from one side of the substrate along the surface of the substrate to excite the surface of the substrate at an interval of one half of a wavelength of the standing wave; and forming a quantum dot with a film differing in lattice constant from a base film forming the surface of the substrate by allowing the film differing in lattice constant to grow on the substrate to form the quantum dots in excited spots of the surface of the substrate.

In the method according to the first aspect, exciting a substrate surface may include intermittently irradiating the laser beam at a specified interval while driving a laser beam source in a direction perpendicular to a laser beam irradiation direction to scan the surface of the substrate.

In the method according to the first aspect, exciting a substrate surface may include changing the wavelength of the laser beam to adjust an interval of the excited spots of the substrate surface in a laser beam irradiation direction.

In the method according to the first aspect, exciting a substrate surface may include changing the specified interval at which the laser beam is intermittently irradiated to adjust an interval of the excited spots of the substrate surface in a direction perpendicular to a laser beam irradiation direction.

In the method according to the first aspect, exciting a substrate surface may include irradiating each laser beam from a plurality of laser beam sources simultaneously or at a different timing to excite the surface of the substrate.

In the method according to the first aspect, exciting a substrate surface may include irradiating laser beams having different wavelengths from each laser beam source to excite the surface of the substrate.

In the method according to the first aspect, exciting a substrate surface may include irradiating the laser beam in a state that a dielectric is positioned to partially cover the surface of the substrate, so that the interval of the excited spots in an area covered with the dielectric differs from the interval of the excited spots in the remaining area.

A second aspect of the present disclosure provides a computer-readable storage medium storing a program for executing a method of forming quantum dots on a surface of a substrate in a computer, the method including: exciting a substrate surface with a laser beam having a standing wave which is irradiated from one side of the substrate along the surface of the substrate to excite the surface of the substrate at an interval of one half of a wavelength of the standing wave; and forming a quantum dot with a film differing in lattice constant from a base film forming the surface of the substrate by allowing the film differing in lattice constant to grow on the substrate to form the quantum dots in excited spots of the surface of the substrate.

A third aspect of the present disclosure provides a substrate processing apparatus for performing a process of forming quantum dots on a surface of a substrate, the apparatus including: a substrate surface excitation process unit configured to perform, prior to forming the quantum dot, a process for exciting desired spots of the surface of the substrate on which the quantum dots are to be formed; and a quantum dot formation process unit configured to perform a process for forming the quantum dots in excited spots of the surface of the substrate by growing a film differing in lattice constant from a base film forming the surface of the substrate to grow on the substrate, the substrate surface excitation process unit including a stage configured to support the substrate, a laser beam source configured to irradiate a laser beam having a standing wave from one side of the substrate placed on the stage along the surface of the substrate and a drive mechanism configured to drive the laser beam source at least in a direction perpendicular to a laser beam irradiation direction.

In the apparatus according to the third aspect, the substrate surface excitation process unit and the quantum dot formation process unit may be independently provided in different processing chambers.

In the apparatus according to the third aspect, the substrate surface excitation process unit and the quantum dot formation process unit may be provided in one processing chamber.

According to the present disclosure, it is possible to accurately form quantum dots in desired positions regardless of the structure of a substrate surface by irradiating a laser beam having a standing wave from one side of a substrate along the substrate surface.

While certain embodiments have been described, these embodiments have been presented by way of example only, and are not intended to limit the scope of the disclosure. Indeed, the novel method, storage medium and apparatus described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A quantum dot forming method for forming quantum dots on a surface of a substrate, the method comprising:
exciting a substrate surface with a laser beam having a standing wave which is irradiated from one side of the substrate along the surface of the substrate to excite the surface of the substrate at an interval of one half of a wavelength of the standing wave; and
forming a quantum dot with a film differing in lattice constant from a base film forming the surface of the substrate by allowing the film differing in lattice constant to grow on the substrate to form the quantum dots in excited spots of the surface of the substrate.

2. The method of claim 1, wherein exciting a substrate surface includes intermittently irradiating the laser beam at a specified interval while driving a laser beam source in a direction perpendicular to a laser beam irradiation direction to scan the surface of the substrate.

3. The method of claim 1, wherein exciting a substrate surface includes changing the wavelength of the laser beam to adjust an interval of the excited spots of the substrate surface in a laser beam irradiation direction.

4. The method of claim 2 wherein exciting a substrate surface includes changing the specified interval at which the laser beam is intermittently irradiated to adjust an interval of the excited spots of the substrate surface in a direction perpendicular to a laser beam irradiation direction.

5. The method of claims 1, wherein exciting a substrate surface includes irradiating each laser beam from a plurality of laser beam sources simultaneously or at a different timing to excite the surface of the substrate.

6. The method of claim 5, wherein exciting a substrate surface includes irradiating laser beams having different wavelengths from each laser beam source to excite the surface of the substrate.

7. The method of claim 1, wherein exciting a substrate surface includes irradiating the laser beam in a state that a dielectric is positioned to partially cover the surface of the substrate, so that the interval of the excited spots in an area covered with the dielectric differs from the interval of the excited spots in the remaining area.

8. A computer-readable storage medium storing a program for executing a method of forming quantum dots on a surface of a substrate in a computer, the method comprising:
exciting a substrate surface with a laser beam having a standing wave which is irradiated from one side of the substrate along the surface of the substrate to excite the surface of the substrate at an interval of one half of a wavelength of the standing wave; and
forming a quantum dot with a film differing in lattice constant from a base film forming the surface of the substrate by allowing the film differing in lattice constant to grow on the substrate to form the quantum dots in excited spots of the surface of the substrate.

9. A substrate processing apparatus for performing a process of forming quantum dots on a surface of a substrate, the apparatus comprising:
a substrate surface excitation process unit configured to perform, prior to forming the quantum dot, a process for exciting desired spots of the surface of the substrate on which the quantum dots are to be formed; and
a quantum dot formation process unit configured to perform a process for forming the quantum dots in excited spots of the surface of the substrate by growing a film differing in lattice constant from a base film forming the surface of the substrate to grow on the substrate, the substrate surface excitation process unit including a stage configured to support the substrate, a laser beam source configured to irradiate a laser beam having a standing wave from one side of the substrate placed on the stage along the surface of the substrate, and a drive mechanism configured to drive the laser beam source at least in a direction perpendicular to a laser beam irradiation direction.

10. The apparatus of claim 9, wherein the substrate surface excitation process unit and the quantum dot formation process unit are independently provided in different processing chambers.

11. The apparatus of claim 9, wherein the substrate surface excitation process unit and the quantum dot formation process unit are provided in one processing chamber.
